(19) United States
(12) Patent Application Publication
(10) Pub. No.: US 2009/0289731 A1
(43) Pub. Date: Nov. 26, 2009

(54) RESONATOR CIRCUIT AND VOLTAGE-CONTROLLED OSCILLATOR USING THE SAME

(75) Inventor: TAI YUEN YANG, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: RALINK TECHNOLOGY CORPORATION, HSINCHU COUNTY (TW)

(21) Appl. No.: 12/421,287

(22) Filed: Apr. 9, 2009

(30) Foreign Application Priority Data
May 21, 2008 (TW) 097118612

(51) Int. Cl. H03B 5/18; H01P 3/08

(52) U.S. Cl. 331/117 FE; 333/204

(57) ABSTRACT

A resonator circuit applied to a voltage-controlled oscillator comprises a switch and a wiring inductance. The switch is connected to a first node and a third node. The wiring inductance has multiple circles, and circles a center from an outermost node to an innermost node through an intermediate node. The outermost node is connected to the first node, the intermediate node is connected to the third node, and the innermost node is connected to the second node.

### BACKGROUND OF THE INVENTION

1. Field of the Invention

The present invention relates to a resonator circuit applied to a voltage-controlled oscillator, and more particularly, to a resonator circuit that is applied to a voltage-controlled oscillator and is capable of switching impedances.

2. Description of the Related Art

With the rapid development of frequency-reducing microwave communication transceivers, there is an urgent demand for low-power, low-cost and highly-integrated transceiver circuits. In a traditional dual-frequency microwave communication transceiver system, the microwave communication transceiver needs two sets of reference frequencies for baseband signal processing, such as modulation. If the two sets of reference frequencies are generated by two sets of voltage-controlled oscillators, the cost of the transceiver circuit increases and the system does not satisfy the demands of the industry.

To overcome the problem, an existing prior art uses two sets of impedance-capacitance tanks (LC tanks) to share a set of current sources. However, although the cost of a set of current sources is saved, this solution increases the circuit area due to the two sets of LC tanks and the larger area for an inductor compared to other components in an IC circuit.

Another prior art uses one set of LC tanks and one set of current sources, by means of capacitance switching. However, such method causes a high electricity loss at the voltage-controlled oscillators, and also suffers from worse phase noise, such as an increasing phase noise.

Another prior art implements two sets of inductances on different metal layers, by means of impedance switching. However, the quality and efficiency of the impedances on the lower metal layer will decrease.

Therefore, it is necessary to develop a resonator circuit applied to a voltage-controlled oscillator, which features low cost and high efficiency.

### SUMMARY OF THE INVENTION

The resonator circuit applied to a voltage-controlled oscillator in accordance with one embodiment of the present invention comprises a switch and a wiring inductance. The switch is connected to a first node and a third node. The wiring inductance has multiple circles, and circles a center from an outermost node to an innermost node through an intermediate node. The outermost node is connected to the first node, the intermediate node is connected to the third node, and the innermost node is connected to the second node.

The voltage-controlled oscillator in accordance with one embodiment of the present invention comprises two resonator circuits, a differential amplifier connected to the two resonator circuits, and a current source connected to the differential amplifier.

### BRIEF DESCRIPTION OF THE DRAWINGS

The invention will be described according to the appended drawings in which:

FIG. 1 shows a resonator circuit applied to a voltage-controlled oscillator in accordance with one embodiment of the present invention; and

FIG. 2 shows a voltage-controlled oscillator in accordance with another embodiment of the present invention.

### PREFERRED EMBODIMENT OF THE PRESENT INVENTION

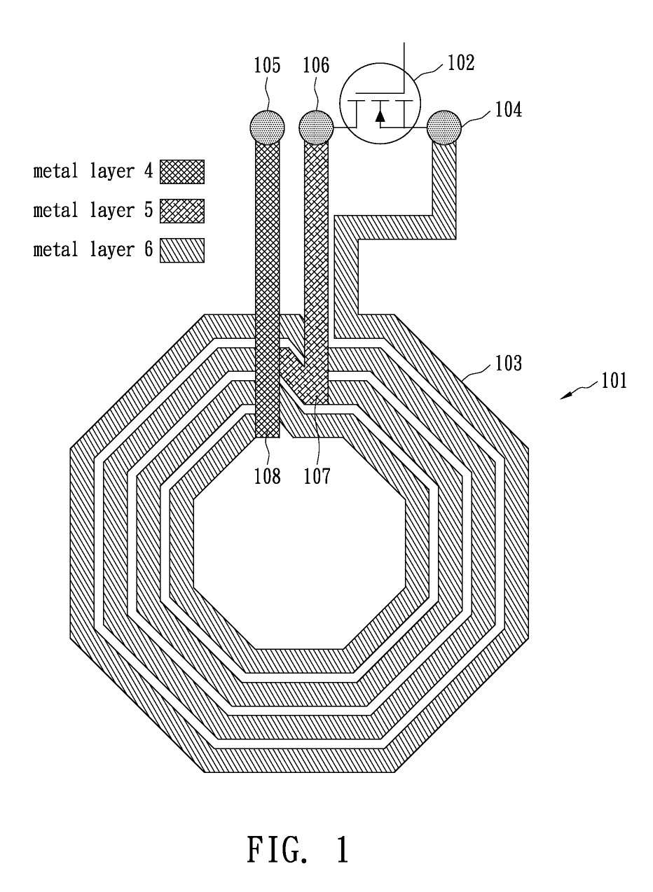

FIG. 1 shows a resonator circuit applied to a voltage-controlled oscillator in accordance with one embodiment of the present invention. The resonator circuit 101 is connected between a first node 104 and a second node 105, and includes a switch 102 and a wiring inductance 103 having multiple circles. The switch 102 is connected to the first node 104 and a third node 106. The wiring inductance 103 circles a center from an outermost node connected to the first node 104 to an innermost node 108 through an intermediate node 107. The intermediate node 107 is connected to the third node 106. The innermost node 108 is connected to the second node 105.

As shown in FIG. 1, when the switch is open, the inductance between the first node 104 and second node 105 is formed by a four-circle inductance. When the switch 102 is closed, the inductance between the first node 104 and second node 105 is formed by a two-layer inductance between the intermediate node 107 and innermost node 108. Therefore, the inductance of the resonator circuit 101 can be controlled by the switch 102.

In a common 0.18 μm process, the resonator circuit 101 is implemented on the top layer and the second top layer, e.g., the metal layers on the sixth layer and the fifth layer. The metal wiring connecting the wiring inductance and the first, second and third nodes is implemented on the fourth layer. The switch 102 can be implemented by a transistor or be controlled by an external signal. The circles of the wiring inductance can be set as four circles, and the inductances corresponding to the open state and closed state of the switch 102 are highly relevant to the reference frequency at 5 GHz and 2.5 GHz.

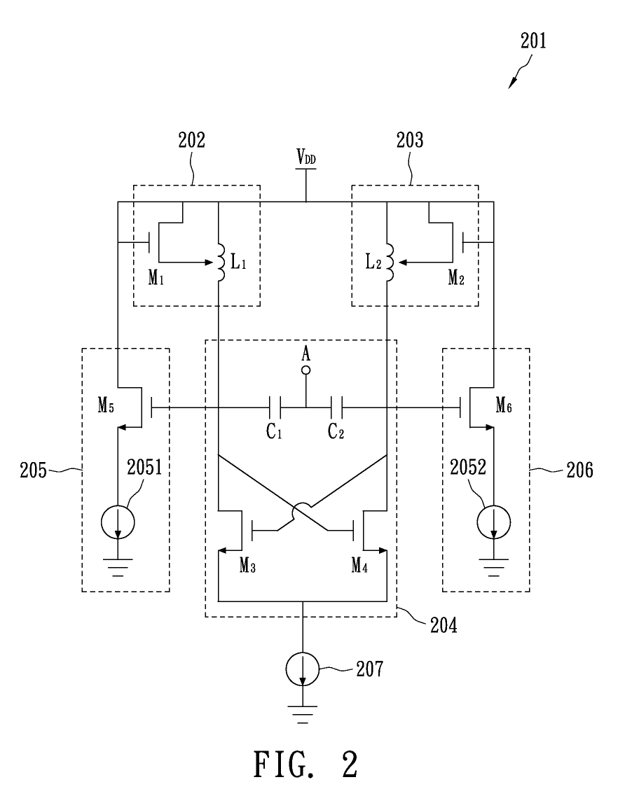

FIG. 2 shows a voltage-controlled oscillator in accordance with another embodiment of the present invention. The voltage-controlled oscillator 201 includes two resonator circuits 202 and 203 as shown in FIG. 1, a differential amplifier 204, two current buffers 205 and 206, and a current source 207. The two resonator circuits 202 and 203 include transistors M1 and M2 and wiring inductances L1 and L2, respectively, so as to provide inductance needed by an inductance-capacitance tank (LC tank). The differential amplifier 204 is connected to the two resonator circuits 202 and 203, and includes transistors M3 and M4, capacitors C1 and C2, an input control voltage node A and two output voltage nodes. The current buffer 205 is connected to one output voltage node of the differential amplifier 204 and the resonator circuits 202, and includes a transistor M5 and a current source 2051. The current buffer 206 is connected to another output voltage node of the differential amplifier 204 and the resonator circuits 203, and includes a transistor M6 and a current source 2052. The current source 207 is used to provide the voltage-controlled oscillator 201 with current. The voltage-controlled oscillator 201 controls an input control voltage at a voltage node A by the input of the differential amplifier 204, and adjusts the oscillation frequency of the voltage-controlled oscillator 201. As shown in FIG. 2, the voltage-controlled oscillator 201 uses the present resonator circuit to achieve the purposes of reducing cost and raising efficiency.

The above-described embodiments of the present invention are intended to be illustrative only. Numerous alternative embodiments may be devised by persons skilled in the art without departing from the scope of the following claims.

What is claimed is:

1. A resonator circuit connected between a first node and a second node and comprising:
a switch connecting the first node and a third node; and
a wiring inductance having multiple circles, the wiring inductance circling a center from an outermost node to an innermost node through an intermediate node;
wherein the outermost node is connected to the first node, the intermediate node is connected to the third node, and the innermost node is connected to the second node.

2. The resonator circuit of claim 1, wherein when the switch is open, the inductance of the resonator circuit is determined by the wiring inductance between the first node and the innermost node.

3. The resonator circuit of claim 1, wherein when the switch is closed, the inductance of the resonator circuit is determined by the wiring inductance between the intermediate node and the innermost node.

4. The resonator circuit of claim 1, wherein the switch is a transistor.

5. The resonator circuit of claim 1, wherein the wiring inductance has an even number of circles.

6. The resonator circuit of claim 5, wherein the wiring inductance has four circles.

7. The resonator circuit of claim 6, wherein the intermediate node is situated on the second or third circle.

8. The resonator circuit of claim 1, wherein the wiring inductance is disposed on a same metal layer.

9. The resonator circuit of claim 8, wherein the wiring inductance is disposed on the top metal layer.

10. The resonator circuit of claim 1, wherein the intermediate node is connected to the third node through a layer immediately below the wiring inductance.

11. The resonator circuit of claim 1, wherein the innermost node is connected to the second node through a layer that is two layers below the wiring inductance.

12. A voltage-controlled oscillator, comprising:
two resonator circuits of claim 1;
a differential amplifier connected to the two resonator circuits; and
a current source connected to the differential amplifier.

13. The voltage-controlled oscillator of claim 12, wherein the differential amplifier comprises:
two transistors, wherein the drain of each transistor is connected to the gate of the other transistor, and the sources of the two transistors are connected;
an input voltage node configured to control an oscillation frequency;
two output voltage nodes; and
two capacitors connected to the input voltage node and two output voltage nodes, respectively.

14. The voltage-controlled oscillator of claim 13, further comprising two current buffers connected to the differential amplifier.

15. The voltage-controlled oscillator of claim 14, wherein each of the two current buffers comprises:
a transistor having a drain connected to the resonator circuit and a gate connected to an output voltage node of the differential amplifier; and
a current source connected to the source of the transistor.
